(19) United States
(12) Patent Application Publication
(10) Pub. No.: US 2026/0361131 A1
(43) Pub. Date: Nov. 12, 2026

(54) THERMAL MANAGEMENT IN CHARGING PUCK

(71) Applicant: Apple Inc., Cupertino, CA (US)

(72) Inventors: Jonathan M. Sullivan, Austin, TX (US); William B. Libeer, Santa Clara, CA (US); Grant S. Haug, San Francisco, CA (US); James C. Wu, Menlo Park, CA (US); Scott W. Slabaugh, Gilroy, CA (US); Amy M. Cuevas, Austin, TX (US); Xiaomeng Wang, Round Rock, TX (US)

(73) Assignee: Apple Inc., Cupertino, CA (US)

(21) Appl. No.: 19/675,267

(22) Filed: May 12, 2026

Related U.S. Application Data
(60) Provisional application No. 63/804,551, filed on May 12, 2025.

(51) Int. Cl. H02J 50/00; H02J 50/10; H02J 50/90; H05K 7/20

(52) U.S. Cl. CPC H02J 50/005; H02J 50/10; H02J 50/90; H05K 7/2039

(57) ABSTRACT

Circuits, methods, and structures that can conduct heat out of an electronic device that is being charged. An example can provide top caps for charging pucks that have multiple layers. A top cap can include a top compliant layer that deform to contact the electronic device over an increased area. This increased contact area can help to conduct heat out of the electronic device and into the charging puck, thereby reducing the temperature of the electronic device during charging, which in turn can allow an electronic device to charged at a higher power. These top caps can further include a second thermally conductive layer under the top compliant layer. The increased conductivity of this layer can further help to conduct heat away from the electronic device to the housing of the charging puck or other charging device.

### CROSS-REFERENCES TO RELATED APPLICATIONS

This application claims the benefit of U.S. Provisional Application No. 63/804,551, filed on May 12, 2025, which is incorporated by reference.

### BACKGROUND

Electronic devices have become ubiquitous. Wearable computing devices, portable computing devices, audio devices, and others accompany us throughout the day. These devices typically include batteries that are used to power them. Often, the batteries in these devices can be recharged using charging devices such as charging pucks or other charging devices.

An electronic device can generate heat when its battery is being charged. This can have negative consequences, such as reducing the lifetime of the electronic devices.

Thus, what is needed are circuits, methods, and structures that can improve the temperature performance of charging devices.

### SUMMARY

Accordingly, embodiments of the present invention can provide circuits, methods, and structures that can improve the temperature performance of charging devices. An illustrative embodiment of the present invention can provide circuits, methods, and structures for effectively transferring and conducting heat out of an electronic device while it is being charged. These and other embodiments of the present invention can provide a top cap for a charging puck or other charging device, where the top cap has multiple layers. The top cap can include a compliant layer that can make improved contact with a charging side of an electronic device that is being charged by a charging puck or other charging device. That is, the compliant layer can deform or compress, or both, to contact the electronic device over an increased area. This increased contact area can help to conduct heat out of the electronic device and into the charging puck or other charging device, thereby reducing the temperature of the electronic device during charging. This top cap can be formed of silicone doped with thermal particles. The thermal particles can be ceramic particles or other material such as boron nitride, carbon, or other material.

These top caps can further include a second thermally conductive layer under the top compliant layer. The increased conductivity of this layer can further help to conduct heat away from the electronic device to the housing of the charging puck or other charging device. This bottom layer can be plastic, nylon-resin, polycarbonate, or other material. The bottom layer can be doped with ceramic based particles or other dopants to improve thermal conductivity. For example, the bottom layer can be doped with boron nitride, carbon, or other material. The bottom layer can be a hard plastic. This or an additional bottom layer can be formed of graphene. The use of graphene can provide thermal conductivity for heat spreading and electrical conductivity for shielding.

In these and other embodiments of the present invention, the top cap can be formed of a single layer of thermally conductive material. This can simplify the manufacturing process of the top cap as compared to a multilayer design. Also, in some embodiments, a silicone based top layer can hinder lateral movement of the electronic device across a top surface of the charging device, which can encourage misalignment between the electronic device and the charging device.

This single layer can be the same as, or substantially similar to, the bottom layer of the two layer embodiment. With this design, the bottom layer is exposed to users as the top layer and additional considerations can be accounted for. For example, the top cap can be doped with thermal particles to increase its thermal conductivity. The amount of thermal particle doping can be limited to avoid tabs and other parts of the top cap from becoming excessively brittle—that is, it can be desirable to limit doping to ensure that sufficient mechanical performance is achievable. But it can also be desirable that enough dopant is added such that the top cap is sufficiently thermally conductive. Further, it can also be desirable to ensure that the mouldability of the material used for the top cap is sufficient such that the top cap can be readily formed. Also, when this nylon-resin layer is the only layer, it is exposed to a user and the cosmetic appearance is important. For example, the nylon-resin can be doped with carbon, but that can leave the top cap looking somewhat darker than might be optimal when a light color, such as white or other lighter color, is desirable.

Transferring heat out of an electronic device can provide several benefits. This thermal spreading can lower the temperature of the electronic device during charging, which can improve battery longevity. The electronic device can be charged more rapidly without reaching preset temperature limitations. The electronic device can have a lower perceived temperature for users after charging.

Various embodiments of the present invention can incorporate one or more of these and the other features described herein. A better understanding of the nature and advantages of the present invention can be gained by reference to the following detailed description and the accompanying drawings.

### BRIEF DESCRIPTION OF THE DRAWINGS

FIG. 1 illustrates an electronic system that can be improved by the incorporation of an embodiment of the present invention;

FIG. 2 is a top view of a charging puck that can be improved by the incorporation of an embodiment of the present invention;

FIG. 3 is a cutaway sideview of a charging puck according to an embodiment of the present invention;

FIG. 4 is a top view of a charging puck according to an embodiment of the present invention;

FIG. 5 though FIG. 8 illustrate structures that can help to spread heat in a charging device according to an embodiment of the present invention;

FIG. 9 illustrates a structure for securing a top cap to a housing according to an embodiment of the present invention;

FIG. 10 illustrates an improvement in temperature performance using a charging puck according to an embodiment of the present invention; and

FIG. 11 is an exploded view of a charging puck according to an embodiment of the present invention.

### DESCRIPTION OF ILLUSTRATIVE EMBODIMENTS

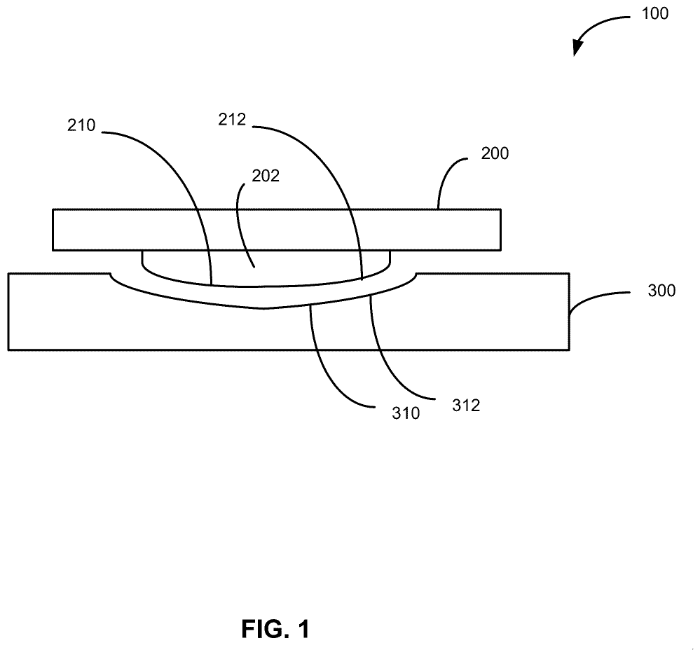

FIG. 1 illustrates an electronic system that can be improved by the incorporation of an embodiment of the present invention. This figure, as with the other figures, is included for illustrative purposes and does not limit either the possible embodiments of the present invention or the claims.

Electronic system 100 can include electronic device 200 being charged by charging puck 300. Charging puck 300 can be a charging puck or other type of charging device. Electronic device 200 can be a wearable device such as a wearable computing device. Electronic device 200 can be a ring, watch, headphones, earbuds, or other wearable device. Electronic device 200 can be a phone, wearable headset, or other type of electronic device. Electronic device 200 can be a portable computing device.

Electronic device 200 can include a charging module 202 that includes a magnet and a charging coil to mate with corresponding magnet 670 and charging coil 640 (both shown in FIG. 6) in charging puck 300.

Charging module 202 of electronic device can include surface 210. During charging, surface 210 can engage the surface of top cap 310 of charging puck 300. Given their respective curvatures, surface 210 can make physical contact with the surface of top cap 310 at circle 212 and point circle. That is, this limited contact area can form a circle of limited width, as shown in the following figure.

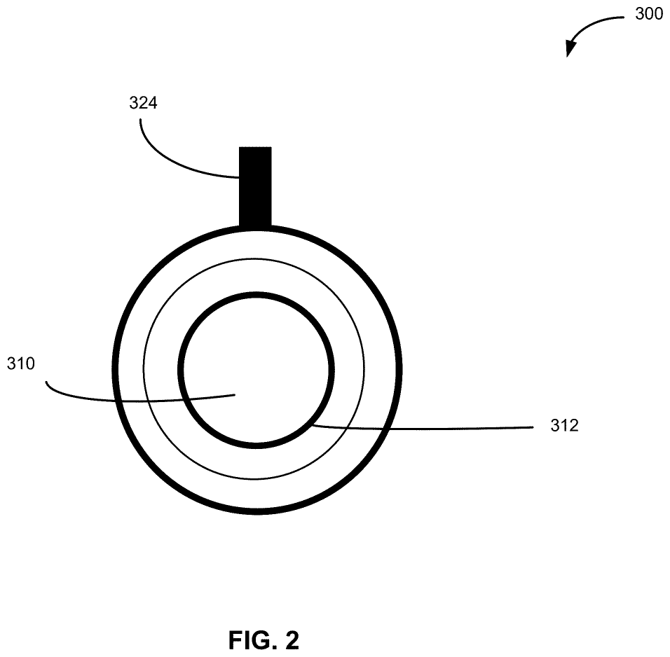

FIG. 2 is a top view of a charging puck that can be improved by the incorporation of an embodiment of the present invention. Charging device or charging puck 300 can be attached to cable 324. Charging device or charging puck 300 can include a charging surface of top cap 310, which can interface with an electronic device being charged by charging device or charging puck 300. The contact area between charging device or charging puck 300 and electronic device 200 can be limited to circle 312. This limited contact area can limit heat transfer from electronic device 200 to charging puck 300, that is, it can increase the thermal impedance through charging puck 300. Accordingly, embodiments of the present invention can provide a top cap having a compliant top layer to conform to a shape of electronic device 200 to increase the contact area. An example is shown in the following figure.

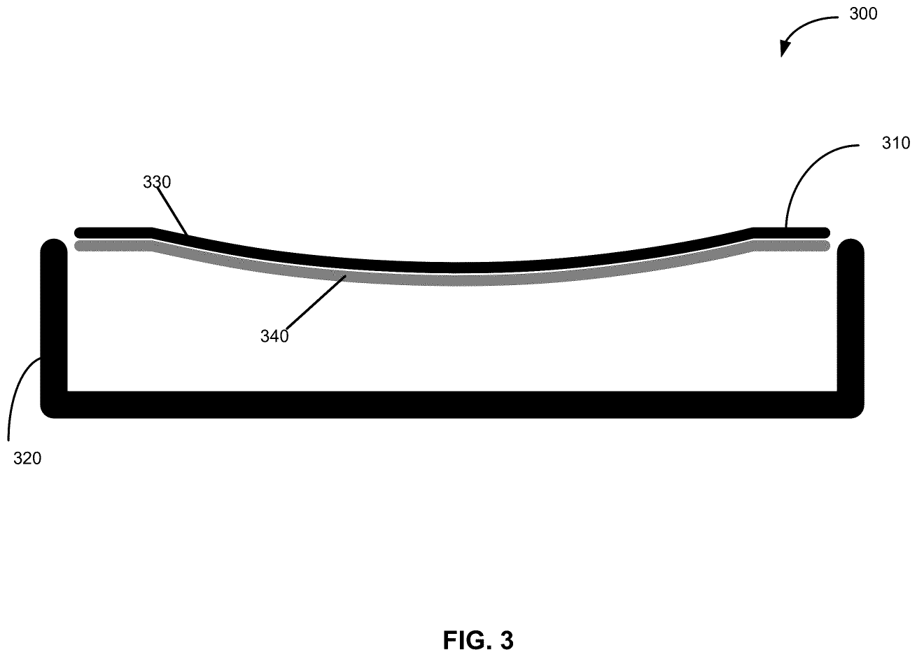

FIG. 3 is a cutaway sideview of a charging puck according to an embodiment of the present invention. Charging puck 300 can include top cap 310 and housing 320. Top cap 310 can include a top layer 330. Top layer 330 can be a compliant layer that can deform or compress, or both, to make contact with a surface of electronic device 200 (shown in FIG. 2.) This deformation or compression, or both, can be improved by the magnetic attraction of magnet 670 (shown in FIG. 6) with a corresponding magnet in electronic device 200. Top cap 310 can further include a bottom layer 340. Bottom layer 340 can be a thermally conductive layer that can conduct heat laterally (as drawn) through top cap 310 to housing 620. This can help to reduce the thermal impedance from electronic device 200, which can help to reduce the temperature of electronic device 200 while being charged by charging puck 300. This reduction in temperature can allow charging puck 300 to provide an increased amount of power to an electronic device (not shown) being charged.

In these and other embodiments of the present invention, top cap 310 can be formed in various ways. For example, top cap 310 can be a single layer of thermally conductive material. In this example, the single layer of top cap 310 can be the same as, or substantially similar to, bottom layer 340.

In these and other embodiments of the present invention, top cap 310 can include bottom layer 340, or top cap 310 can be formed of bottom layer 340. Bottom layer 340 can be formed of various materials. For example, bottom layer 340 can be formed of plastic, polycarbonate, or other material. Bottom layer 340 can be formed of a nylon-based resin. Bottom layer 340 can be a hard plastic. Bottom layer 340 can be doped with ceramic particles or other materials such as boron nitride, carbon, or other material to improve thermal conductivity.

Top layer 330 of top cap 310 can be placed over bottom layer 340, or top layer 330 can be omitted. Top layer 330 can be formed of silicone, rubber, or other compliant material. The silicone or other material can be doped with thermal particles to improve thermal conductivity. The thermal particles can be ceramic particles or other material such as boron nitride, carbon, or other material. In some circumstances, a top layer 330 formed of silicone can inhibit lateral movement of electronic device 200 across a surface of charging puck 300. This can inhibit proper alignment of electronic device 200 and charging puck 300 when electronic device 200 is charged by charging puck 300.

When bottom layer 340 is used under top layer 330, bottom layer 340 can be doped with thermal particles to increase its thermal conductivity. The amount of thermal particle doping can be limited to avoid tabs and other parts of the top cap from becoming excessively brittle—that is, it can be desirable to ensure that sufficient mechanical performance is achievable. But it can also be desirable that enough dopant is added such that bottom layer 340 is sufficiently thermally conductive. It can also be desirable to ensure that the mouldability of the material used for the bottom layer 340 is sufficient such that the top cap can be readily formed.

When bottom layer 340 is used without top layer 330, the bottom layer 340 can be top cap 310. Top cap 310 can be exposed to users and additional considerations can be accounted for. As before, top cap 310 can be doped with thermal particles to increase its thermal conductivity. The amount of thermal particle doping can be limited to avoid tabs 370 (shown in FIG. 6.) and other parts of the top cap 310 from becoming excessively brittle—that is, it can be desirable to ensure that sufficient mechanical performance is achievable. But it can also be desirable that enough dopant is added such that top cap 310 is sufficiently thermally conductive. It can also be desirable to ensure that the mouldability of the material used for top cap 310 is sufficient such that top cap 310 can be readily formed. Also, when top layer 330 is not used, bottom layer 340 is exposed to a user and the cosmetic appearance is important. For example, the nylon-resin can be doped with carbon, but that can leave the top cap looking somewhat darker than might be optimal when a light color, such as white or other lighter color, is desirable.

These and other embodiments of the present invention can include these and other layers. For example, the top compliant layer can be formed of an upper layer that can deform or conform to a shape of a surface of the electronic device and a lower layer that can compress.

Again, top layer 330 of top cap 310 can be a compliant layer. Top layer 330 can compress to fit the contours of surface 210 of electronic device 200. Top layer 330 can also or instead deform to fit the contours of surface 210 of electronic device 200. Either or both this compression and deformation can increase the area of contact between electronic device 200 and charging puck 300. An example is shown in the following figure.

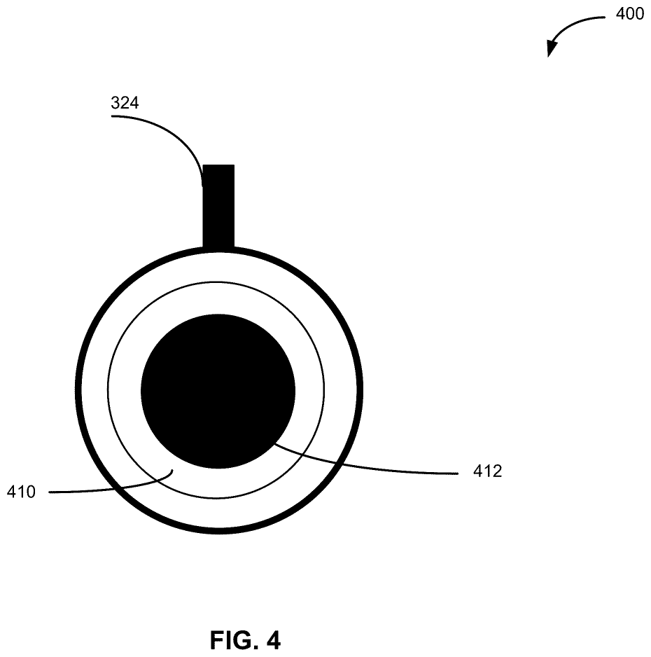

FIG. 4 is a top view of a charging puck according to an embodiment of the present invention. In this example, a contact region between electronic device 200 and charging puck 300 can be the much larger area 412 of top cap 410. The larger contacting area 412 can reduce the thermal impedance between electronic device 200 and charging puck 300. This can conduct heat more efficiently from electronic device 200 to charging puck 300 where it can be dissipated through a housing, such as housing 620 (shown in FIG. 6.)

Cable 324 can convey power from an external source to control electronics 660, which can drive a waveform on charging coil 640 (both shown in FIG. 6) to charge electronic device 200.

These and other embodiments of the present invention can provide structures for efficiently spreading heat in a charging device, such as a charging puck. These structures can be added as an additional element to the charging device, or they can replace one or more elements of a charging device. Examples are shown in the following figures.

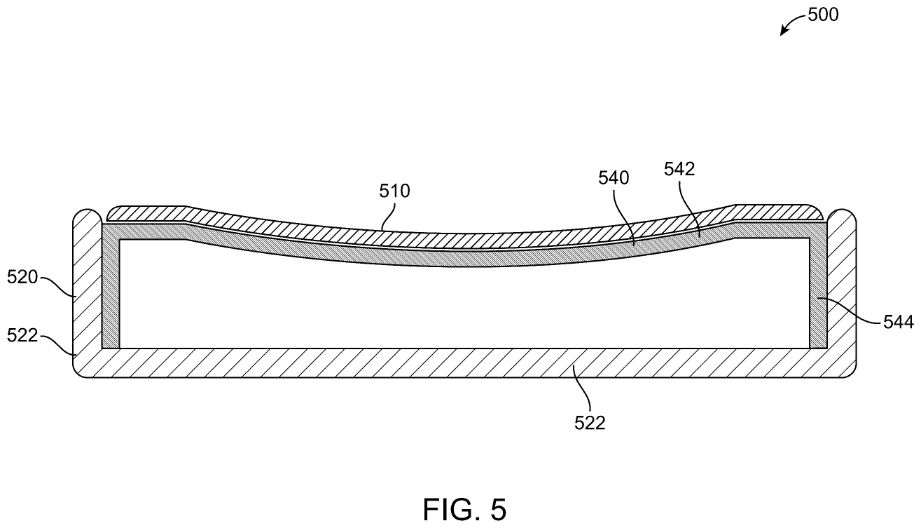

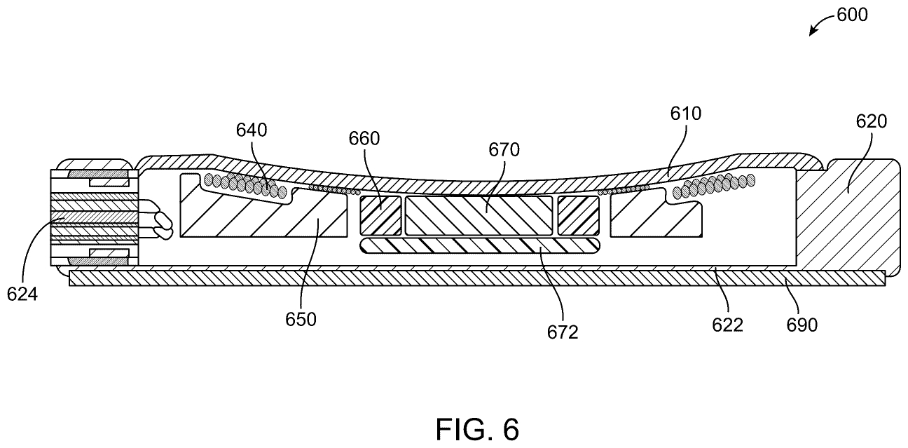

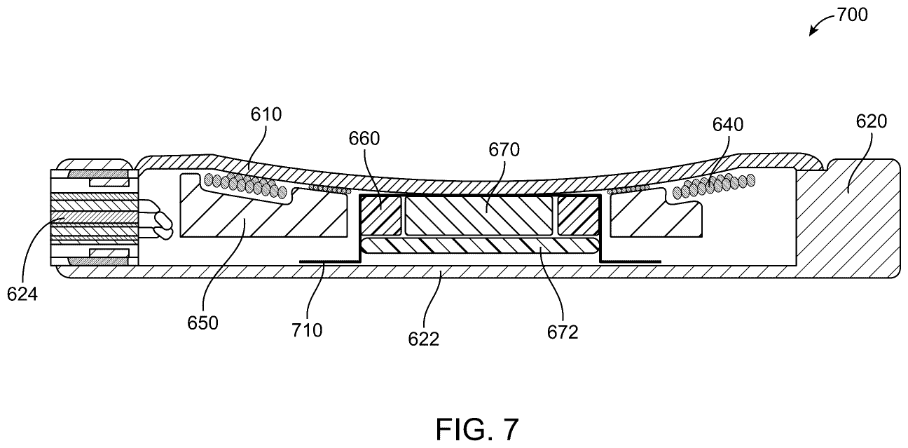

FIG. 5 though FIG. 8 illustrate structures that can help to spread heat in a charging device according to an embodiment of the present invention. In FIG. 5, charging puck 500 can include top cap 510 and housing 520. Charging puck 500 can include internal heat spreader 540. Internal heat spreader 540 can help to remove heat from an electronic device (not shown) being charged at top cap 510 and spread it to housing 520. Internal heat spreader 540 can include a lateral portion 542 under top cap 510. Lateral portion 542 can be formed with or attached to vertical portion or vertical portions 544. Vertical portion 544 can help to spread heat from top cap 510 to housing 520. Vertical portions 544 can extend along all or parts of sidewall 522 of housing 520. Vertical portions 544 can be configured as tabs that can be used to thermally connect internal heat spreader 540 to housing 520.

Internal heat spreader 540 can be formed as part of or separate from top cap 510. Again, vertical portion 544 can be formed as part of or separate from lateral portion 542 of internal heat spreader 540. For example, top cap 510 can be formed as a first molding shot and internal heat spreader 540 be formed as a second molding shot, where the first and second shot form a single piece. Top cap 510 and internal heat spreader 540 can instead be formed as separate pieces and included in charging puck 500 during manufacturing. Either these or other methods can allow top cap 510 to be formed of a material that provides a desirable appearance, since top cap 510 is typically visible to a user, and can allow internal heat spreader 540 to be formed of a material having an improved thermal conductivity. Internal heat spreader 540 can be formed of thermally conductive plastic, epoxy, resin, nylon, or other material. The material forming internal heat spreader can be doped with carbon, silver, or other material. Lateral portion 542 and vertical portions 544 can be formed of the same or different materials. One or more layers of graphene can be placed on one or more surfaces of internal heat spreader 540, or the internal heat spreader can be formed using a layer of graphene. A graphene layer can provide thermal conductivity to internal heat spreader 540. A graphene layer can also help to reduce a volume consumed by internal heat spreader 540.

These shots can be various types of molding shots in these and other embodiments of the present invention. For example, either or both the first and second shots can be formed by injection molding. Either or both the first and second shots can be formed by low-injection-pressure overmold (LIPO.) The use of LIPO can enable a layer to have a decreased thickness. This decreased thickness can help to increase an efficiency of the charging of an electronic device by a charging device, such as a charging puck.

In this example, internal heat spreader 540 can be added as an element to charging puck 500. In these and other embodiments of the present invention, elements that provide improved thermal spreading can supplement or replace existing structures. An example is shown in the following figure.

FIG. 6 illustrates a charging puck with an housing portion having improved thermal spreading capabilities. Charging puck 600 can include top cap 610 and housing 620. Top cap 610 and housing 620 can house charging coil 640, ferrite 650, control electronics 660, magnet 670, and magnetic shield 672. Cable 624 can include conductors 626 for conveying power from an external source (not shown) to control electronics 660. Control electronics 660 can provide waveforms to drive currents in charging coil 640. Top cap 610 can provide a surface for engaging with an electronic device (not shown) that is being charged by the charging puck 600 or other charging device. Ferrite 650 can redirect magnet fields created by charging coil 640 towards top cap 610 to improve magnetic field coupling to a corresponding coil in electronic device 200. Magnet 670 can work in concert with a corresponding magnet in the electronic device to align and attach the electronic device to charging puck 600 or other charging device. Magnet 670 can be various types of magnets, such as a permanent magnet.

In this example, a portion of housing 620 can be replaced or supplemented by heat spreader 690. Specifically, in this example, a portion of a bottom 622 of housing 620 can be replaced with heat spreader 690. Heat spreader 690 can provide mechanical structure to housing 620, and can conduct heat away from an electronic device (not shown) being charged by charging device or charging puck 600. By providing mechanical support to housing 620, heat spreader 690 can allow a bottom 622 of housing 620 to be thinner, thus spreading heat without adding significant size to charging puck 600. Heat spreader 690 can be formed of various materials, such as copper or other material having a good thermal conductivity.

In these and other embodiments of the present invention, other structures, such as other internal heat spreaders, can be included in charging puck 600. These internal heat spreaders can move heat away from hot-spots in charging puck 600. An example is shown in the following figure.

FIG. 7 illustrates a charging puck with an internal heat spreader to provide an improved thermal spreading capabilities. Charging puck 700 can include top cap 610 and housing 620. Top cap 610 and housing 620 can house charging coil 640, ferrite 650, control electronics 660, magnet 670, and magnetic shield 672. Cable 624 can include conductors 626 for conveying power from an external source (not shown) to control electronics 660. Control electronics 660 can provide waveforms to drive currents in charging coil 640. Top cap 610 can provide a surface for engaging with an electronic device (not shown) that is being charged by the charging device or charging puck 600. Ferrite 650 can redirect magnet fields created by charging coil 640 towards top cap 610 to improve magnetic field coupling to a corresponding coil in electronic device 200. Magnet 670 can work in concert with a corresponding magnet in the electronic device to align and attach the electronic device to charging device or charging puck 600. Magnet 670 can be various types of magnets, such as a permanent magnet.

In this example, internal heat spreader 710 can be formed around control electronics 660 and magnet 670. This configuration can move heat away from control electronics 660 and magnet 670, which might otherwise be hotter than other portions of charging puck 700. Internal heat spreader 710 can be formed of copper or other thermally conductive material. Internal heat spreader 710 can be formed of a layer of graphene. Using a layer of graphene can reduce a volume consumed by internal heat spreader 710 and can provide a good thermal conductivity. Internal heat spreader 710 can be attached to bottom 622 of housing to provide a pathway for heat from internal heat spreader 710.

In these and other embodiments of the present invention, structures already used in a charging device can be modified to improve heat spreading. An example is shown in the following figure.

FIG. 8 illustrates an example of a charging device having a housing with improved thermal conductivity. In this example, a portion of charging puck 800 is shown. Housing 820 can include a bottom 822 having extensions 824. Extensions 824 can provide a larger effective surface area for bottom 822 of housing 820, thereby improving the thermal conductivity of housing 820.

These and other embodiments of the present invention can replace, supplement, or add other components to a charging device such as a charging puck to improve heat spreading. For example, potting glue or other potting material can be added to the internal portion of a charging puck. For example, a phase change material can be used where an addition of heat changes a phase of a potting or other material as a way of absorbing heat for a later dissipation. A thickness of a housing can be increased. A mass of a housing or other components can be increased. Internal spreaders can be added to other locations in a charging puck, for example below magnet 670 or below magnetic shield 672. These heat spreaders can be formed of graphene. The use of graphene can reduce a volume consumed by a heat spreader and can provide good thermal conductivity. Ferrite 650 can be increased in thickness to improve its thermal conductivity. Thermal adhesives can be used internally.

To further help move heat, a thermal connection between a top cap and a housing can be improved. An example is shown in the following figure.

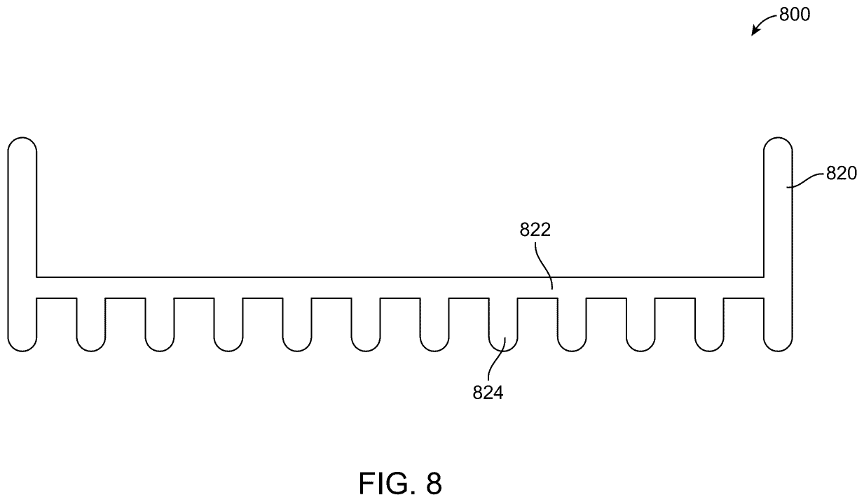

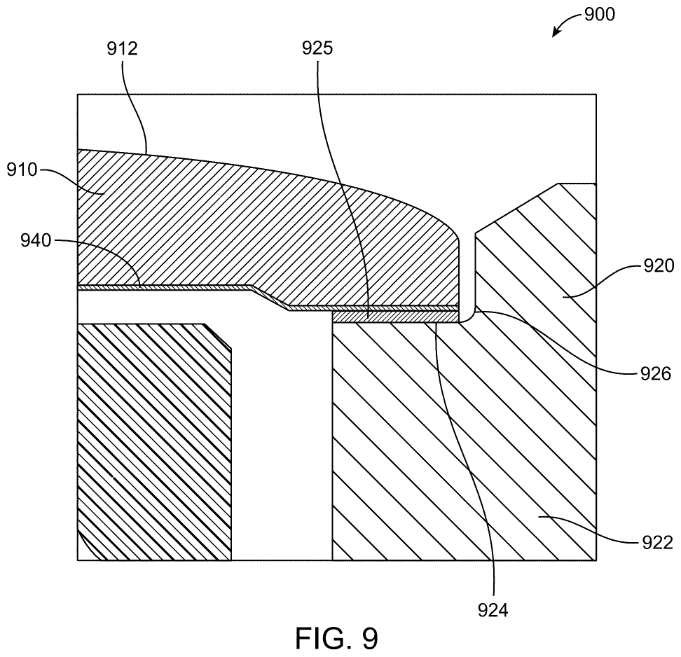

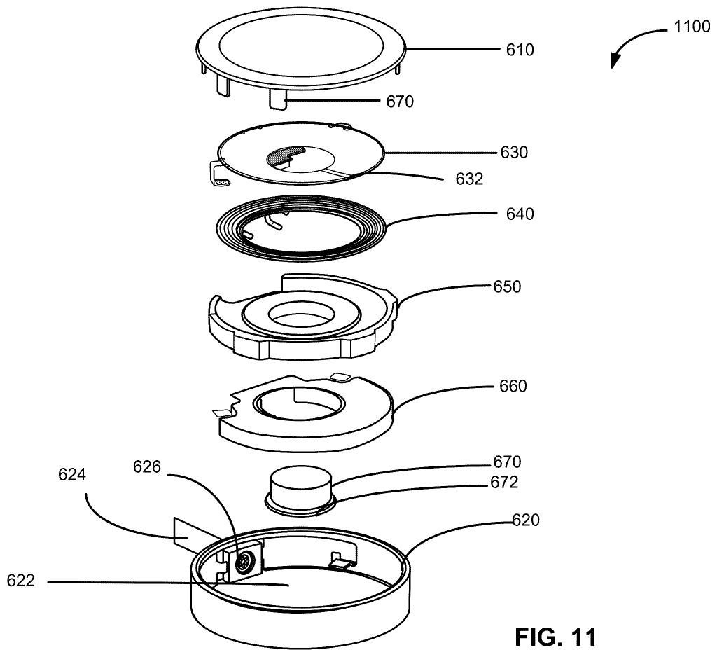

FIG. 9 illustrates a structure for securing a top cap to a housing according to an embodiment of the present invention. Charging puck 900 can include top cap 910 and housing 920. Top cap 910 and housing 920 can house magnet 670, magnetic shield 672, charging coil 640, ferrite 650, control electronics 660 (all shown in FIG. 11), a subset of these, or some or all of these and other components.

Top cap 910 can be formed of a thermally conductive nylon-based plastic or other plastic, glass-filled nylon, resin, or other material. E-shield 940, and other e-shields provided by embodiments of the present invention, can be formed on the underside of top cap 910. E-shield 940, and other e-shields provided by embodiments of the present invention, can be formed of conductive ink, carbon, silver, or other material. The coating for e-shield 940 can be formed by pad printing, vapor deposition, jet spraying, 3D printing, or other method. E-shield 940 can be formed of a layer of graphene. Using graphene can provide an e-shield with good thermal and electrical conductive properties. E-shield 940 can act to limit electromagnet interference and reduce electric fields at charging surface 912 of top cap 910 of charging puck 900, while permitting the passage of magnetic fields.

These and other embodiments of the present invention can provide a physical connection or contact between top cap 910 and housing 920 that can provide mechanical support for a device at charging surface 912 and can provide a good thermal connection between e-shield 940 and housing 920 in order to help improve heat spreading. In this example, notch 926 can be formed in a top of sidewall 922 of housing 920. Surface 924 of notch 926 can be at least partially coated with a layer of thermally conductive glue 925. Surface 924 can be made to be fairly wide to provide a wide contacting area to e-shield 940 of top cap 910. This wide area can provide good mechanical support for an electronic device (not shown) positioned at contacting surface 912. The wide contacting area between e-shield 940 and surface 924 of housing 920 can provide a good thermal conductivity between them. The use of conductive glue can further improve the electrical connection. To further improve the thermal conductivity between e-shield 940 and surface 924 of housing 920, housing 920 can be formed of aluminum or other material that has been de-anodized.

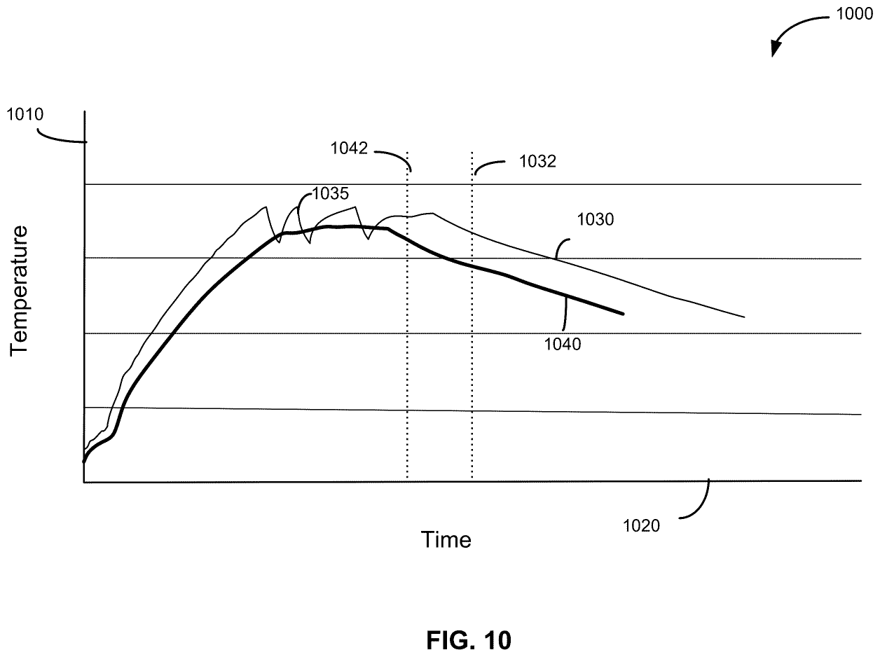

FIG. 10 illustrates an improvement in temperature performance using a charging puck according to an embodiment of the present invention. Electronic devices being charged by conventional charging devices can reach temperatures 1030 and can take time 1032 to charge. Electronic devices charged by embodiments of the present invention that utilize a top cap 310 might only reach temperatures 1040 and can be charged in the shorter time 1042. This reduced temperature can lengthen battery life of the electronic device. It can also provide a lower temperature electronic device to a user after charging, making for a more pleasant user experience and offering a higher level of perceived quality. As shown, this improved temperature performance can provide a reduced charging time. This is at least partially the result of not having to slow or throttle the charging due to excess temperatures in the electronic device being charged, which can appear in this graph as pulses 1035.

FIG. 11 is an exploded view of a charging puck according to an embodiment of the present invention. Charging puck 1100 can include top cap 610, housing 620, e-shield 630, charging coil 640, ferrite 650, control electronics 660, magnet 670, and magnetic shield 672.

Cable 624 can include conductors 626 for conveying power from an external source (not shown) to control electronics 660. Control electronics 660 can provide waveforms to drive currents in charging coil 640. E-shield 630, charging coil 640, ferrite 650, control electronics 660, magnet 670, and magnetic shield 672 can be housed in a recess at bottom 622 of housing 620.

Top cap 610 can provide a surface for engaging with an electronic device (not shown) that is being charged by the charging puck 600 or other charging device. The electronic device can be a watch, ring, earbuds, headphones, or other wearable electronic device or wearable computing device. The electronic device can be another type of device, such as a headset, phone, laptop, tablet, or other electronic device. Top cap 610 can present an aesthetically pleasing surface to a user of charging puck 600 or other charging device.

E-shield 630 can be formed of a low resistance material to block electromagnetic fields and emissions from charging coil 640. E-shield 630 can include slot 632 to increase the impedance of e-shield 630 to induced or eddy currents that would otherwise reduce coupling efficiency.

Charging coil 640 can be located on ferrite 650. Ferrite 650 can redirect magnet fields created by charging coil 640 towards top cap 610 to improve magnetic field coupling to a corresponding coil in electronic device 200.

Magnet 670 can work in concert with a corresponding magnet in the electronic device to align and attach the electronic device to charging device or charging puck 300. Magnet 670 can be various types of magnets, such as a permanent magnet. Magnet 670 can be a Z-pole radial magnet as described in co-pending U.S. provisional patent application No. ______, having attorney docket number 090911-P72279USP1, which is incorporated by reference. Magnet 670 can be positioned on magnetic shield 672. Magnetic shield 672 can act as a backplate to direct magnetic flux towards a corresponding magnet in an electronic device being charged.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A charging device comprising:
a housing having a recess; and
a top cap, wherein the top cap forms a charging surface for engaging an electronic device being charged by the charging device, wherein the top cap comprises a thermally conductive layer covering the recess in the housing.

2. The charging device of claim 1 wherein the top cap is formed of resin.

3. The charging device of claim 1 wherein the top cap is formed of a nylon-based resin.

4. The charging device of claim 3 wherein the top cap is doped with boron nitride.

5. The charging device of claim 3 wherein the top cap is doped with carbon.

6. The charging device of claim 1 wherein the top cap is polycarbonate doped with thermally conductive particles.

7. The charging device of claim 1 wherein the charging device is a charging puck.

8. A charging device comprising:
a housing having a recess;
a top cap, wherein the top cap forms a charging surface for engaging an electronic device being charged by the charging device, wherein the top cap covers the recess in the housing and comprises:
a compliant layer to physically contact an electronic device when the electronic device is charged by the charging device; and
a thermally conductive layer positioned adjacent to the compliant layer.

9. The charging device of claim 8 wherein the compliant layer comprises a silicone layer.

10. The charging device of claim 9 wherein the compliant layer is doped with thermally conductive materials.

11. The charging device of claim 10 wherein the thermally conductive layer is a nylon-based resin.

12. The charging device of claim 11 wherein the thermally conductive layer is doped with ceramic particles.

13. The charging device of claim 11 wherein the thermally conductive layer is doped with boron nitride.

14. The charging device of claim 11 wherein the thermally conductive layer is doped with carbon.

15. A charging device comprising:
a housing having a recess;
a top cap, wherein the top cap forms a charging surface for engaging an electronic device being charged by the charging device, wherein the top cap comprises a thermally conductive layer covering the recess in the housing;
a charging coil;
a ferrite supporting the charging coil;
an alignment magnet; and
control electronics to receive power from an external source and drive waveforms on the charging coil to inductively transfer power to an electronic device being charged by the charging device,
wherein the charging coil, ferrite, alignment magnet, and control electronics are housed in the recess of the housing under the top cap.

16. The charging device of claim 15 wherein the top cap is formed of resin.

17. The charging device of claim 15 wherein the top cap is formed of a nylon-based resin.

18. The charging device of claim 17 wherein the top cap is doped with boron nitride.

19. The charging device of claim 17 wherein the top cap is doped with carbon.

20. The charging device of claim 15 wherein the top cap is polycarbonate doped with thermally conductive particles.
